(19) United States
(12) Patent Application Publication
(10) Pub. No.: US 2021/0055421 A1
(43) Pub. Date: Feb. 25, 2021

(54) ELECTRICAL CIRCUIT ACROSS OPTICAL ELEMENT TO DETECT DAMAGE

(71) Applicant: Continental Automotive Systems, Inc., Auburn Hills, MI (US)

(72) Inventors: Cleveland Eugene Rayford, II, Camarillo, CA (US); Jacob A. Bergam, Santa Barbara, CA (US); Luis Alfredo Villalobos-Martinez, Camarillo, CA (US)

(73) Assignee: Continental Automotive Systems, Inc., Auburn Hills, MI (US)

(21) Appl. No.: 16/547,765

(22) Filed: Aug. 22, 2019

(51) Int. Cl. G01S 17/93; G01S 7/486; G01S 7/484

(52) U.S. Cl. CPC G01S 17/936; G01S 17/89; G01S 7/484; G01S 7/486

(57) ABSTRACT

A Lidar system includes an illumination system that includes an optical element and a light emitter aimed at the optical element. An exit window is positioned to receive light directed from the optical element. The illumination system may include a light-receiving element including a beam dump and/or a photodetector. The light-receiving element is positioned to receive light directed from the optical element. The light-receiving element and the exit window are on the same side of the optical element. The illumination system may include a light shield between the photodetector and the exit window. The light shield is positioned to shield the photodetector from light passing through the exit window.

### BACKGROUND

A solid-state Lidar system includes a photodetector, or an array of photodetectors that is essentially fixed in place relative to a carrier, e.g., a vehicle. Light is emitted into the field of view of the photodetector and the photodetector detects light that is reflected by an object in the field of view. For example, a Flash Lidar system emits pulses of light, e.g., laser light, into essentially the entire field of view. The detection of reflected light is used to generate a 3D environmental map of the surrounding environment. The time of flight of the reflected photon detected by the photodetector is used to determine the distance of the object that reflected the light.

The solid-state Lidar system may be mounted on a vehicle to detect objects in the environment surrounding the vehicle and to detect distances of those objects for environmental mapping. The output of the solid-state Lidar system may be used, for example, to autonomously or semi-autonomously control operation of the vehicle, e.g., propulsion, braking, steering, etc. Specifically, the system may be a component of or in communication with an advanced driver-assistance system (ADAS) of the vehicle.

### BRIEF DESCRIPTION OF THE DRAWINGS

FIG. 1 is a perspective view of a vehicle including a Lidar system.

FIG. 2 is a perspective view of the Lidar system

FIG. 3 is perspective view of an illumination system of the Lidar system.

FIG. 4 is a perspective view of an optical element of the illumination system and an electrical circuit across the optical element.

FIG. 5A is a schematic view of the optical element and the electrical circuit.

FIG. 5B is the schematic view of FIG. 5A with the optical element damaged.

FIG. 6 is a schematic view of another embodiment of the optical element and the electrical circuit.

FIG. 7A is a schematic view of the optical element and a portion of the electrical circuit of FIG. 6 including schematically shown current paths.

FIG. 7B is the schematic view of FIG. 7A with the optical element damaged.

FIG. 7C is the schematic view of FIG. 7A with a plurality of possible current paths.

FIG. 8A is a block diagram of the Lidar system.

FIG. 8B is a block diagram of another example of the Lidar system.

FIG. 9 is an example method performed by the Lidar system and/or the vehicle.

FIG. 10 is another example method performed by the Lidar system and/or the vehicle.

### DETAILED DESCRIPTION

With reference to the Figures, wherein like numerals indicate like parts throughout the several views, a system 10 is generally shown. The system 10 may be a component of a light detection and ranging (Lidar) system 12. Specifically, the system 10 may be an illumination system of the Lidar system 12. The system 10 includes an optical element 14 and a light emitter 16 aimed at the optical element 14. The system 10 includes a controller 18 in communication with the light emitter 16 and an electrical circuit 20 across the optical element 14 and in communication with the controller 18.

Since the electrical circuit 20 is across the optical element 14, the electrical circuit 20 indicates the integrity of the optical element 14, i.e., whether the optical element 14 is intact or damaged. In the event the optical element 14 is intact, i.e., undamaged, the electrical circuit 20 is intact. In the event the optical element 14 is damaged, the electrical circuit 20 is broken. The voltage across the electrical circuit 20 when the electrical circuit 20 is broken is different than the voltage across the electrical circuit 20 when the electrical circuit 20 is intact. These different voltages are used to control the operation of the light emitter 16, as described further below. Specifically, the system 10 is designed such that the light emitter 16 is operational when the electrical circuit 20 is intact, i.e., indicating the optical element 14 is intact, and such that the light emitter 16 is not operational when the electrical circuit 20 is broken, i.e., indicating that the optical element 14 is damaged. The optical element 14, when intact, alters light from the light emitter 16, e.g., shapes the light, prior to exiting the system 10. When the optical element 14 is damaged, the optical element 14 may not properly alter the light from the light emitter 16, resulting in undesirable light emissions exiting the system 10. Thus, the inoperability of the light emitter 16 when the optical element 14 is damaged prevents all or substantially all undesirable light emission from the system 10.

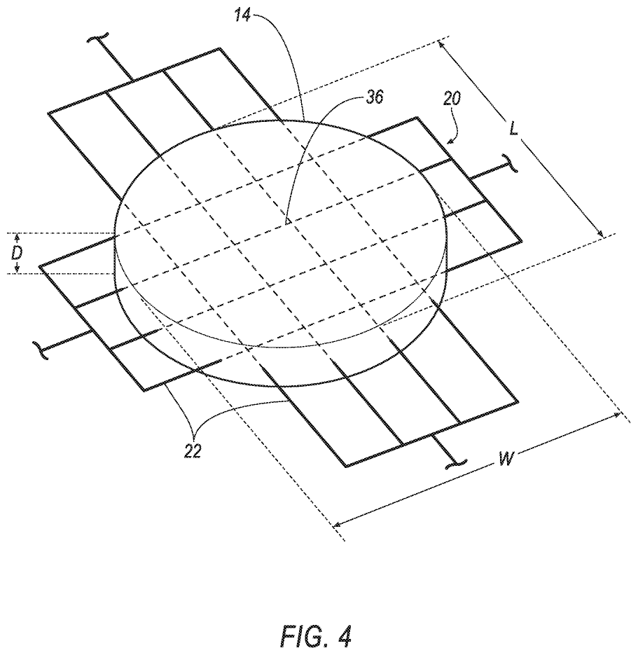

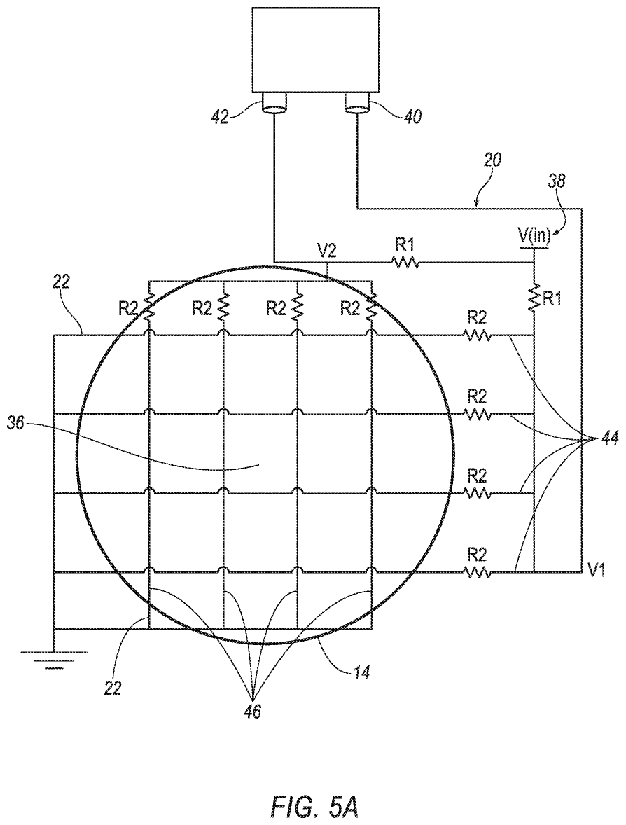

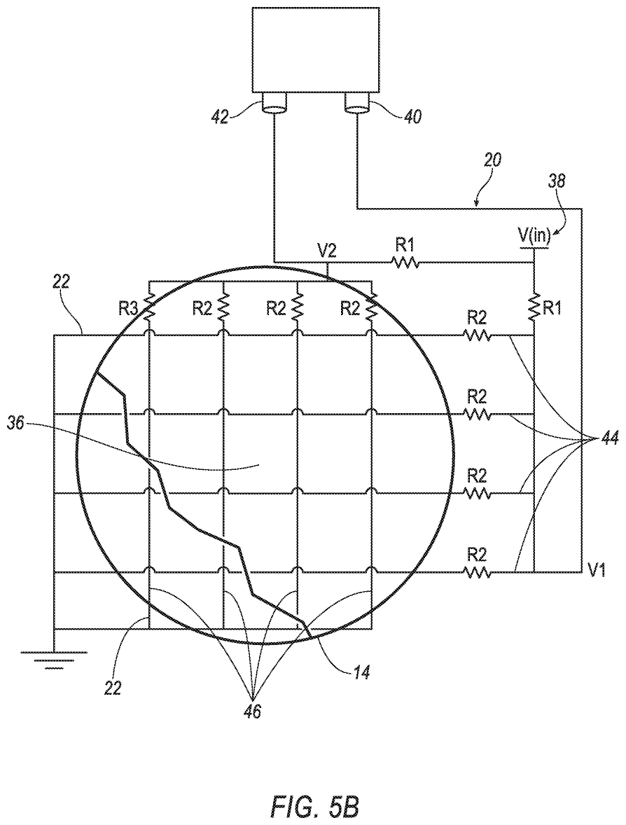

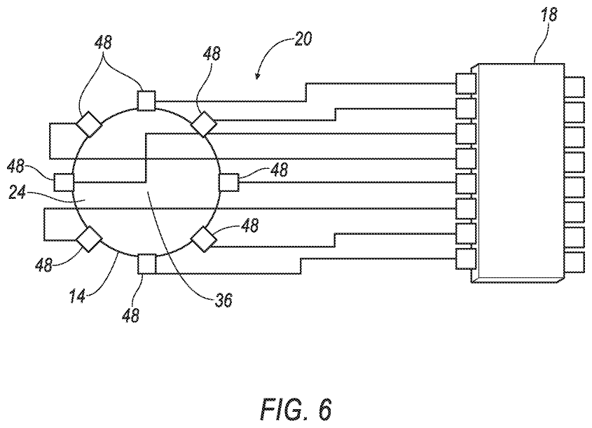

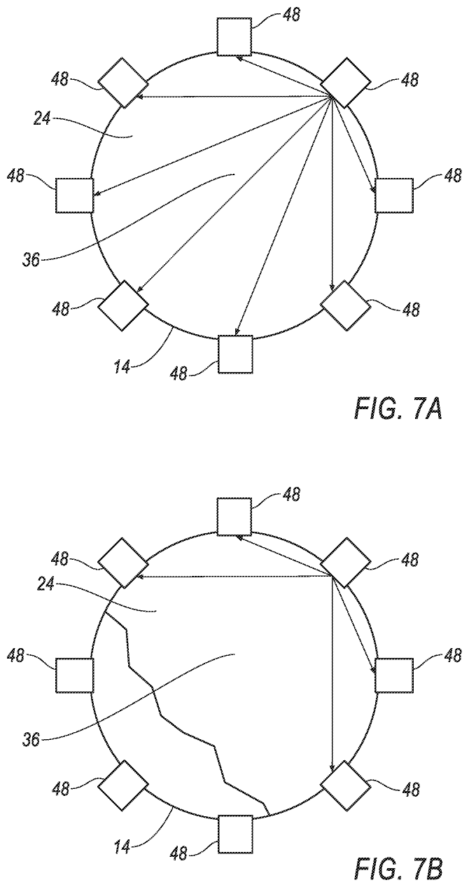

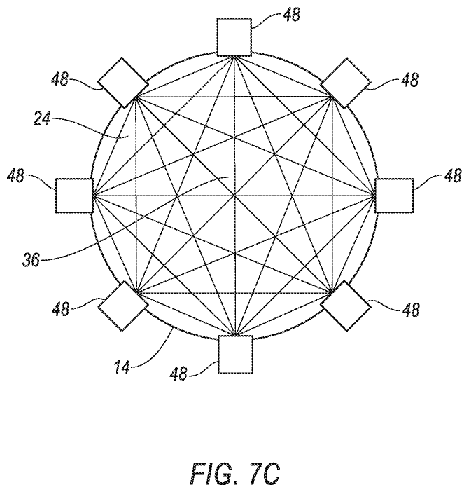

One example of the electrical circuit 20 is shown in FIGS. 4 and 5 and another example of the electrical circuit 20 is shown in FIGS. 6-7C, as described further below. In FIGS. 4 and 5, the electrical circuit 20 includes a wire 22, e.g., a plurality of wires 22, extending across the optical element 14. In such an example, damage to the optical element 14 breaks the wire 22. When voltage is supplied to the electrical circuit 20, the voltage across the electrical circuit 20 is different when the wire 22 is broken as compared to when the wire 22 is unbroken, thus indicating damage to the optical element 14. In FIGS. 6-7C, the optical element 14 includes an electrically-conductive layer 24 that forms a portion of the electrical circuit 20. In such an example, damage to the optical element 14 breaks the electrically-conductive layer 24. When voltage is supplied to the electrical circuit 20, the voltage across the electrical circuit 20 is different when the electrically-conductive layer 24 is broken as compared to when the electrically-conductive layer 24 is unbroken, thus indicating damage to the optical element 14.

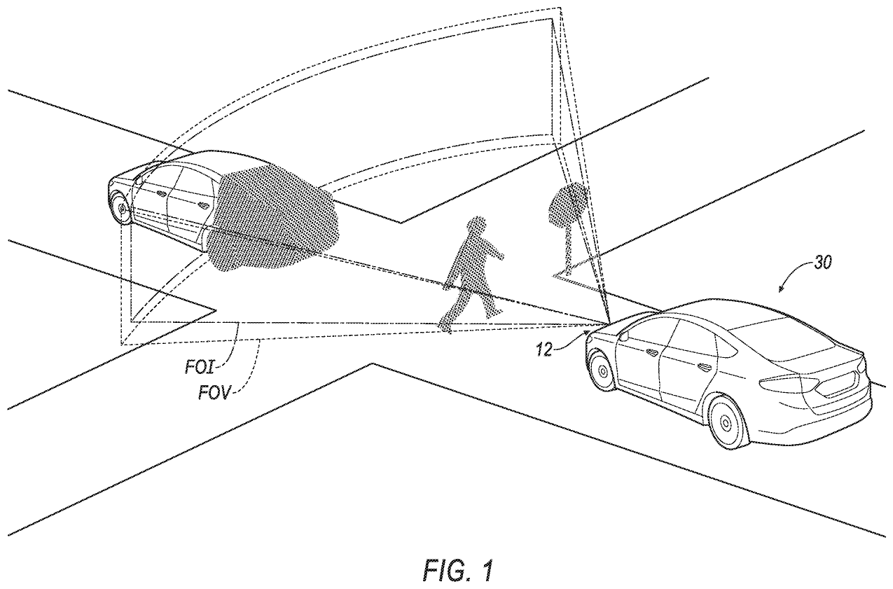

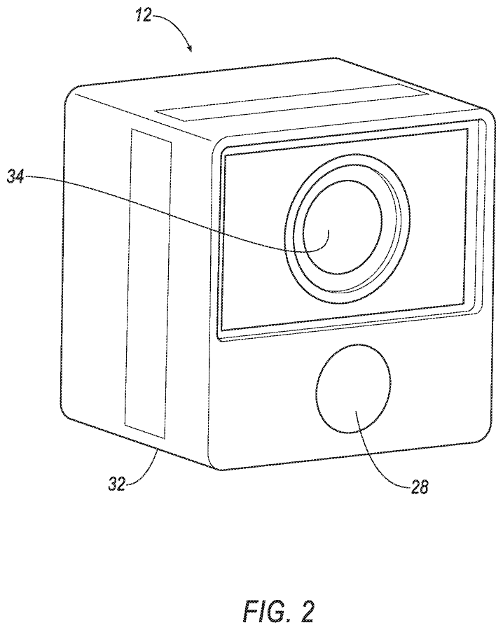

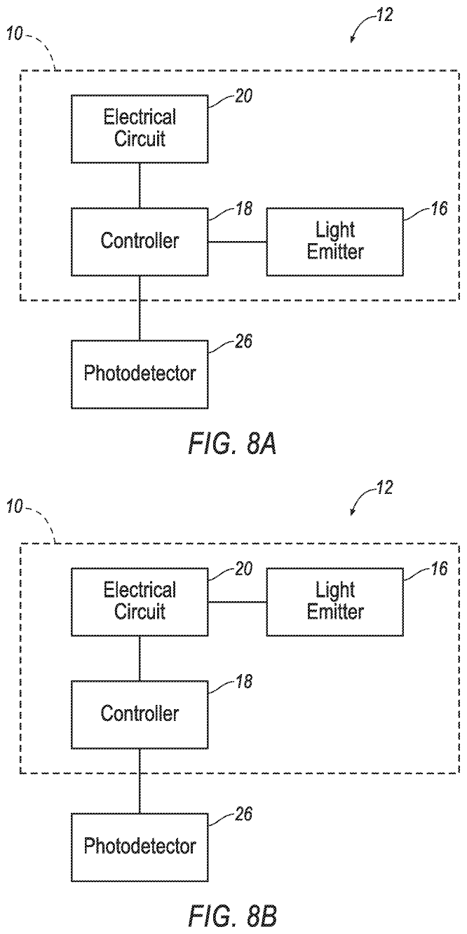

As set forth above, the system 10 may be a component of a Lidar system 12. With reference to FIG. 1, the Lidar system 12 emits light and detects the emitted light that is reflected by an object, e.g., pedestrians, street signs, vehicles 30, etc. Specifically, the light emitter 16 emits light through an exit window 34 to a field of illumination FOI. The light emitted from the light emitter 16 is altered, e.g., shaped, by the optical element 14 before exiting the exit window 34. The Lidar system 12 includes a light-receiving system (shown in FIGS. 2 and 8 and described below) that has a field of view FOV that overlaps the field of illumination FOI and receives the reflected light. The light-receiving system may include a photodetector 26 (FIGS. 8A-B) and receiving optics 28 (FIG. 2), as are known. The controller 18 is in communication with the light emitter 16 for controlling the emission of light from the light emitter 16. The controller 18 may be a component of the system 10 and/or the Lidar system 12.

The Lidar system 12 is shown in FIG. 1 as being mounted on a vehicle 30. In such an example, the Lidar system 12 is operated to detect objects in the environment surrounding the vehicle 30 and to detect distance of those objects for environmental mapping. The output of the Lidar system 12 may be used, for example, to autonomously or semi-autonomously control operation of the vehicle 30, e.g., propulsion, braking, steering, etc. Specifically, the Lidar system 12 may be a component of or in communication with an advanced driver-assistance system (ADAS) of the vehicle 30. The Lidar system 12 may be mounted on the vehicle 30 in any suitable position and aimed in any suitable direction. As one example, the Lidar system 12 is shown on the front of the vehicle 30 and directed forward. The vehicle 30 may have more than one Lidar system 12 and/or the vehicle 30 may include other object detection systems, including other Lidar systems. The vehicle 30 is shown in FIG. 1 as including a single Lidar system 12 aimed in a forward direction merely as an example. The vehicle 30 shown in the Figures is a passenger automobile. As other examples, the vehicle 30 may be of any suitable manned or un-manned type including a plane, satellite, drone, watercraft, etc.

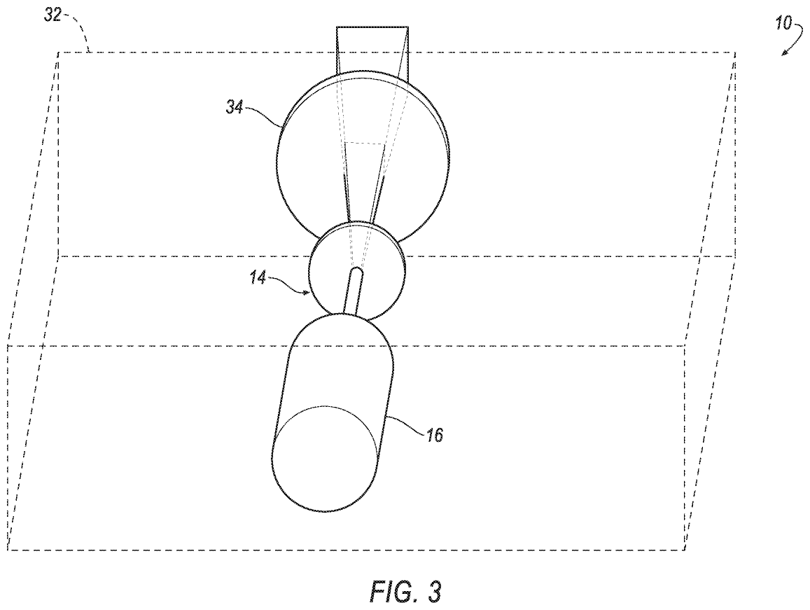

The Lidar system 12 may be a solid-state Lidar system. In such an example, the Lidar system 12 is stationary relative to the vehicle 30. For example, the Lidar system 12 may include a casing 32 (shown in FIGS. 2 and 3 and described below) that is fixed relative to the vehicle 30, i.e., does not move relative to the component of the vehicle 30 to which the casing 32 is attached, and a silicon substrate of the Lidar system 12 is supported by the casing 32.

As a solid-state Lidar system, the Lidar system 12 may be a flash Lidar system. In such an example, the Lidar system 12 emits pulses of light into the field of illumination FOI. More specifically, the Lidar system 12 may be a 3D flash Lidar system that generates a 3D environmental map of the surrounding environment, as shown in part in FIG. 1. An example of a compilation of the data into a 3D environmental map is shown in the field of view FOV and the field of illumination FOI in FIG. 1.

In such an example, the Lidar system 12 is a unit. For example, with reference to FIG. 2, the casing 32 may enclose the other components of the Lidar system 12 and may include mechanical attachment features to attach the casing 32 to the vehicle 30 and electronic connections to connect to and communicate with electronic system of the vehicle 30, e.g., components of the ADAS. For example, the exit window 34 extends through the casing 32 and the casing 32 houses the assembly and the light emitter 16. The exit window 34 includes an aperture extending through the casing 32 and may include a lens in the aperture.

The casing 32, for example, may be plastic or metal and may protect the other components of the Lidar system 12 from environmental precipitation, dust, etc. In the alternative to the Lidar system 12 being a unit, components of the Lidar system 12, e.g., the light emitter 16 and the light-receiving system, may be separated and disposed at different locations of the vehicle 30.

With continued reference to FIG. 1, the light emitter 16 emits light into the field of illumination FOI for detection by the light-receiving unit when the light is reflected by an object in the field of view FOV. The light emitter 16 may be, for example, a laser. The light emitter 16 may be, for example, a semiconductor laser. In one example, the light emitter 16 is a vertical-cavity surface-emitting laser (VCSEL). As another example, the light emitter 16 may be a diode-pumped solid-state laser (DPSSL). As another example, the light emitter 16 may be an edge emitting laser diode. The light emitter 16 may be designed to emit a pulsed flash of light, e.g., a pulsed laser light. Specifically, the light emitter 16, e.g., the VCSEL or DPSSL or edge emitter, is designed to emit a pulsed laser light. The light emitted by the light emitter 16 may be, for example, infrared light. Alternatively, the light emitted by the light emitter 16 may be of any suitable wavelength. The Lidar system 12 may include any suitable number of light emitters 16, i.e., one or more in the casing 32. In examples that include more than one light emitter 16, the light emitters 16 may be identical or different.

With reference to FIG. 3, the light emitter 16 may be stationary relative to the casing 32. In other words, the light emitter 16 does not move relative to the casing 32 during operation of the system 10, e.g., during light emission. The light emitter 16 may be mounted to the casing 32 in any suitable fashion such that the light emitter 16 and the casing 32 move together as a unit.

As set forth above, the Lidar system 12 may be a staring, non-moving system. As another example, the Lidar system 12 may include elements to adjust the aim of the Lidar system 12. For example, the Lidar system 12 may include a beam steering device (not shown) that directs the light from the light emitter 16 into the field of illumination FOI. The beam steering device may be a micromirror. For example, the beam steering device may be a micro-electro-mechanical system 10 (MEMS) mirror. As an example, the beam steering device may be a digital micromirror device (DMD) that includes an array of pixel-mirrors that are capable of being tilted to deflect light. As another example, the MEMS mirror may include a mirror on a gimbal that is tilted, e.g., by application of voltage. As another example, the beam steering device may be a liquid-crystal solid-state device.

As set forth above, the light emitter 16 is aimed at the optical element 14. Specifically, the optical element 14 includes a light-shaping region 36 (described further below) and the light emitter 16 is aimed at the light-shaping region 36. The light emitter 16 may be aimed directly at the optical element 14 or may be aimed indirectly at the optical element 14 through intermediate reflectors/deflectors, diffusers, optics, etc.

The light-shaping region 36 of the optical element 14 shapes the light from the light emitter 16, e.g., by diffusion, scattering, etc. The light-shaping region 36 may be transmissive, as shown in FIG. 3, i.e., transmits light from the light emitter 16 through the light-shaping region 36. In other words, the optical element 14 is designed to transmit light from the light emitter 16. In such an example, the electrical circuit 20 may be on a surface of the light emitter 16 and/or may be embedded in the light emitter 16 (as shown in FIG. 3). As another example, the light-shaping region 36 may be reflective, i.e., reflects light from the light emitter 16. In other words, the optical element 14 is designed to reflect light from the light emitter 16. In an example in which the light-shaping region 36 is reflective, the light-shaping region 36 may be a coating on a relatively less transmissive substrate. In such an example, the electrical circuit 20 may be on a surface of the coating and/or may be embedded in the coating and/or substrate.

The optical element 14 shapes light that is emitted from the light emitter 16. The light-shaping region 36 shapes, e.g., diffuses, scatters, etc., light from the light emitter 16. Specifically, the light emitter 16 is aimed at the optical element 14, i.e., substantially all of the light emitted from the light emitter 16 reaches the optical element 14. As one example of shaping the light, the optical element 14 diffuses the light, i.e., spreads the light over a larger path and reduces the concentrated intensity of the light. In other words, the optical element 14 is designed to diffuse the light from the light emitter 16. As another example, the optical element 14 scatters the light, e.g., a hologram). “Unshaped light” is used herein to refer to light that is not shaped, e.g., not diffused or scattered, by the optical element 14, e.g., resulting from damage to the optical element 14. Light from the light emitter 16 may travel directly from the light emitter 16 to the optical element 14 or may interact with additional components between the light emitter 16 and the optical element 14. The shaped light from the optical element 14 may travel directly to the exit window 34 or may interact with additional components between the optical element 14 the exit window 34 before exiting the exit window 34 into the field of illumination FOI.

The optical element 14 directs the shaped light to the exit window 34 for illuminating the field of illumination FOI exterior to the Lidar system 12. In other words, the optical element 14 is designed to direct the shaped light to the exit window 34, i.e., is sized, shaped, positioned, and/or has optical characteristics to direct at least some of the shaped light to the exit window 34.

The optical element 14 may be of any suitable type that shapes and directs light from the light emitter 16 toward the exit window 34. For example, the optical element 14 may be or include a diffractive optical element 14, a diffractive diffuser, a refractive diffuser, a computer-generated hologram, a blazed grating, etc.

As set forth above, the electrical circuit 20 is across the optical element 14. In other words, components of the electrical circuit 20 extend from one end of the optical element 14 to another end of the optical element 14 along an elongated length of the optical element 14. In other words, the optical element 14 may have a depth D that is thin relative to a length L of the optical element 14 and the electrical circuit 20 may extend across the length L. The electrical circuit 20 may be across the light-shaping region 36. The electrical circuit 20, e.g., the wires 22 of FIGS. 4-5 and the layer 24 in FIGS. 6-7C) do not affect the light-shaping function of the optical element 14 and/or are designed with the optical element 14 so as to achieve the desired light-shaping function.

In the example shown in FIGS. 4-5C, the electrical circuit 20 includes the wire 22 extending across the optical element 14. For example, the electrical circuit 20 may include more than one wire 22 extending across the optical element 14, as shown in FIGS. 4-5C. The wires 22 may extend through the optical element 14, as shown in FIGS. 4-5C. In other words, the wires 22 may be embedded in the optical element 14. In such an example, the optical element 14 may be plastic and may be formed by plastic injection molding, e.g., by overmolding onto the wires 22. As another example, the wires 22 may be on a surface of the optical element 14. In such an example, the wires 22 may be assembled to the surface of the optical element 14 by, for example, additive manufacturing (i.e., 3D printing), adhesive, screen printing, lithography, conductive ink printing, electrical deposition, powder coating, etc.

The wires 22 may be, as an example, conductive metal. The wires 22 may be silver, copper, aluminum, gold, molybdenum, zing, brass, tin, steel, titanium. Alternatively, the wires 22 may be of any suitable material that is electrically conductive. The wires 22 may have high light transmissivity and/or a thickness that does not interfere with the light-shaping function of the optical element 14 (i.e., may be thin enough to avoid meaningful interference with the light-shaping function of the optical element 14).

With reference to FIG. 5A, the electrical circuit 20 may be a voltage divider. In the example in FIG. 5A, the electrical circuit 20 has two voltage dividers. Specifically, the electrical circuit 20 has a voltage supply 38, a first input 40 to the controller 18, and a second input 42 to the controller 18. The wires 22 are arranged in a first set 44 and a second set 46 across the optical element 14. The wires 22 of the first set 44 are in rows and the wires 22 of the second set 46 are in rows that are transverse, e.g., perpendicular, to the rows of the first set 44. The first set 44 and the second set 46 are each components of separate voltage dividers. The wires 22 of the first set 44 are in parallel and the wires 22 of the second set 46 are in parallel.

The two voltage dividers in the example of FIG. 5A may be identical and common features in FIG. 5A are identified with common numerals. Each voltage divider of the electrical circuit 20 includes a first resistor R1 between the voltage supply 38 and the set 44, 46. Specifically, the set 44, 46 extends from a node to ground and the first resistor R1 is between the voltage supply 38 and the node. A second resistor R2 is along each wire 22. Specifically, the second resistors R2 are between the node and ground. The node is connected to the input 40, 42. The second resistors R2 in parallel have a lower resistance than the first resistor R1.

Voltage is supplied at the voltage supply 38 to identify integrity of the optical element 14. The voltage may be supplied at the voltage supply 38 by the controller 18, e.g., the controller 18 may provide an instruction to supply voltage at the voltage supply 38. When the optical element 14 is intact, the voltage at the input is a result of the voltage divider. In the event the optical element 14 is damaged, at least one of the wires 22 is broken. In such an event, when voltage is supplied at the voltage supply 38, the voltage at the input 40, 42 is different than the voltage when each wire 22 is intact, thus indicating damage to the optical element 14.

With reference to FIG. 6, the optical element 14 includes a layer 24 of electrically-conductive material that forms a portion of the electrical circuit 20. The layer 24 may be the entire optical element 14 (i.e., all material of the optical element 14) or one of a plurality of layers 24 of the optical element 14 (i.e., layers 24 arranged along the depth D of the optical element 14). In any event, the layer 24 is spread across the length L and width W of the optical element 14, e.g., in a plane along the length and width. The layer 24 of electrically-conductive material does not affect the light-shaping function of the optical element 14 and/or are is designed with the optical element 14 so as to achieve the desired light-shaping function. As one example, the layer 24 may be designed to shape the light emitted from the light emitter 16. In an example in which the optical element 14 is transmissive, the layer 24 of electrically-conductive material may have high light transmissivity that does not interfere with the light-shaping function of the optical element 14. The electrically-conductive material may be, for example, crystals, plastic, ceramic, inorganic non-metallic material (e.g., titanium dioxide), ceramic metal (also referred to as cermet), composite material, semi-conductive material, etc. As an example, the layer 24 may be a material type that shapes the light emitted from the light emitter 16.

With continued reference to FIG. 6, the electrical circuit 20 includes terminals 48 spaced from each other on the electrically-conductive layer 24. In other words, the terminals 48 are in electrical communication with the electrically-conductive layer 24. The terminals 48 are in communication with the controller 18, e.g., by wired connection. The terminals 48 may be disposed on a peripheral edge of the optical element 14. The terminals 48 are an electrically conductive layer 24. The terminals 48 may be identical to each other.

The electrically-conductive layer 24 completes the electrical circuit 20 between the terminals 48. The controller 18 supplies voltage to one of the terminals 48 and voltage across the optical element 14 is detected by at least one other of the terminals 48. In the example shown in FIG. 7A, voltage across the optical element 14 is detected by each of the other terminals 48. The detection of voltage at the other terminals 48, e.g., as received and identified by the controller 18, identifies the integrity of the optical element 14. In other words, when the optical element 14 is intact, the voltage across the optical element 14 is detected by the other terminals 48. Current paths are schematically shown in FIG. 7A to illustrate the detection of voltage by the other terminals 48. In the event the optical element 14 is damaged, the current paths are disrupted and/or eliminated so that at least one of the other terminals 48 receives no voltage or a different amount of voltage relative to when the optical element 14 is intact, thus indicating damage to the optical element 14.

In the example where the terminals 48 are identical, any one of the terminals 48 may be supplied with voltage and the controller 18 may cycle through a routine of supplying voltage to different ones of the terminals 48 and detecting the voltage across the optical element 14 to determine integrity of the optical element 14. In other words, the routine of supplying voltage to different ones of the terminals 48 results in a grid of current paths to increase the test area of the optical element 14 that is checked for integrity. All of the current paths of the grid are simultaneously shown in FIG. 7C for illustrative purposes, and it should be appreciated that the voltage is supplied to a single terminal 48 at any time (one example of which is shown in FIG. 7B).

The electrical circuit 20 is designed to break when the optical element 14 is damaged. In other words, the electrical circuit 20 is positioned, sized, shaped, has a material type, etc., that results in breakage of the electrical circuit 20 when the optical element 14 is damages. Damage includes a crack in the optical element 14 and surface damage including melting. Damage to the optical element 14 disrupts the electrical circuit 20 by disrupting and/or breaking some or all of the electrical circuit 20. As an example, with reference to FIG. 5B, the wires 22 are designed to break in the event the optical element 14 is damaged in the vicinity of the wires 22. For example, in the event the optical element 14 cracks or is otherwise damaged, e.g., melting, the wires 22 in the vicinity of the damage will break. One such example is shown in FIG. 5B. With reference to FIGS. 6-7C, the layer 24 is designed to break in the event the optical element 14 is damaged. As set forth above, in one example the layer 24 may be the entire optical element 14, i.e., all material, in which case damage to the optical element 14 is also damage to the layer 24. In an example in which the layer 24 is one of a plurality of layers 24 of the optical element 14, the layer 24 is designed to break in the vicinity of damage to the optical element 14.

The system 10 is designed to disable operation of the light emitter 16 when the optical element 14 is damaged. Disabling the operation of the light emitter 16 may be an affirmative step, e.g., actively deciding not to power the light emitter 16, or passive, e.g., not powering the light emitter 16 in the absence of instruction to do so.

The controller 18 is programmed to control the light emitter 16 based on voltage received by the controller 18 from the electrical circuit 20. As one example, the controller 18 may be programmed to supply voltage, to the controller 18 through the electrical circuit 20 and wait for detection of a voltage from the electrical circuit 20 indicating the optical element 14 is intact. The controller 18 may be pre-programmed with a value of the voltage to be detected from the electrical circuit 20 that results from the voltage supplied at the voltage supply 38 when the electrical circuit 20 is intact. In the event the controller 18 receives the voltage from the electrical circuit 20 indicating that the electrical circuit 20 is intact, the controller 18 powers the light emitter 16. The controller 18 may be programmed to wait for the voltage indicating that the electrical circuit 20 is intact, and in the absence of such voltage, e.g., resulting from a different voltage across the electrical circuit 20 due to a break in the electrical circuit 20, the controller 18 does not power the light emitter 16. As another example, the controller 18 may be programmed to detect the voltage other than a voltage indicating that the electrical circuit 20 is intact and, in response to such a detection, decide to disable operation of the light emitter 16 (which may include not powering the light emitter 16 and/or taking an active step to disable the power emitter and/or prevent emission of light from the exit window 34). In such an example, the controller 18 may be programmed to instruct the vehicle 30, e.g., the ADAS, so that the vehicle 30 notifies a vehicle operator and/or disables the vehicle 30 or a vehicle system 10, e.g., the ADAS.

The controller 18 is in communication with the light emitter 16 and the electrical circuit 20, e.g., by wired or wireless connection capable of sending and/or receiving signals. The controller 18 may be in communication individually with the light emitter 16 and the electrical circuit 20, as shown in FIG. 8A. As another example, the electrical circuit 20 may be between the controller 18 and the light emitter 16, as shown in FIG. 8B, such that instruction to the light emitter 16 is communicated through the electrical circuit.

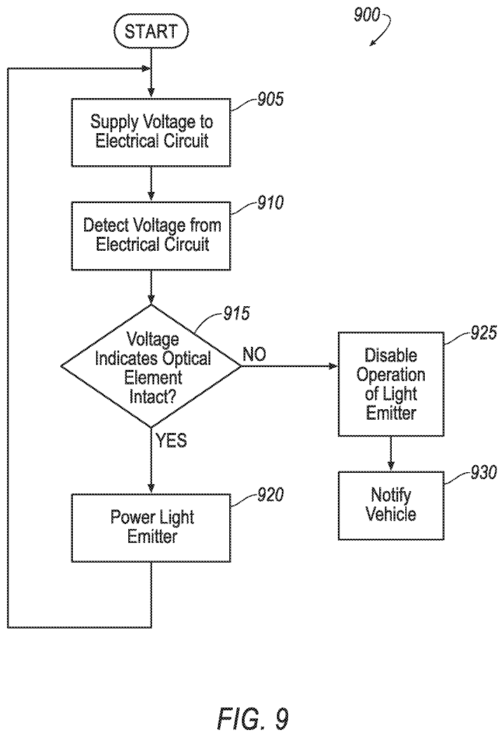

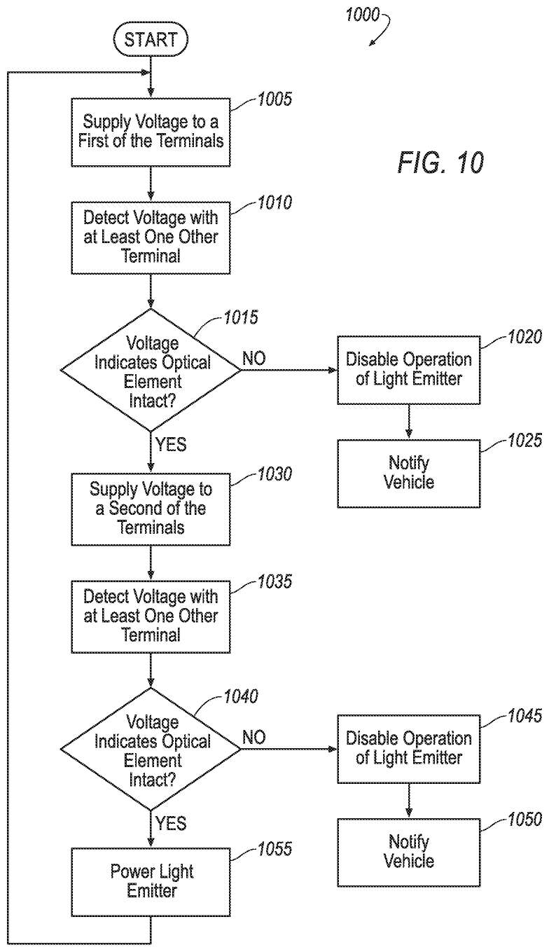

The controller 18 may also be referred to as a computer. The controller 18 may be a microprocessor-based controller or field programmable gate array (FPGA), or a combination of both, implemented via circuits, chips, and/or other electronic components. In other words, the controller 18 is a physical, i.e., structural, component of the system 10. For example, the controller 18 includes a processor, memory, etc. The memory of the controller 18 may store instructions executable by the processor, i.e., processor-executable instructions, and/or may store data. The controller 18 may be in communication with a communication network of the vehicle 30 to send and/or receive instructions from the vehicle 30, e.g., components of the ADAS. Specifically, the instructions stored on the memory of the controller 18 may include instructions to perform the method 900 in FIG. 9 or the method 1000 in FIG. 10. Use herein (including with reference to the method 900 and method 1000) of “based on,” “in response to,” and “upon determining,” indicates a causal relationship, not merely a temporal relationship.

The methods 900, 1000 shown in FIGS. 9 and 10, respectively, are initiated to illuminate a scene, e.g., external to the vehicle 30, and to determine range of objects in the scene. The scene is illuminated only if no damage to the optical element 14 is detected. The controller 18 may initiate the method 900, 1000 based on, for example, instructions from an ADAS of the vehicle 30.

With reference to FIG. 9, the method 900 may use the example of the optical element 14 shown in FIGS. 4-5A. In block 905, the memory stores instructions to supply voltage to the electrical circuit 20. The controller 18 may supply the voltage directly to the electrical circuit 20 or may instruct an intermediate component to supply the voltage to the electrical circuit 20. The level of voltage supplied to the electrical circuit 20 is known, i.e., predetermined.

In block 910, the memory may store instructions to detect voltage from the electrical circuit 20. Detecting voltage includes receiving voltage from the electrical circuit 20 or detecting the absence of voltage from the electrical circuit 20 after voltage was supplied in block 905.

The memory stores instructions to control operation of a light emitter 16 based on the level of voltage detected from the electrical circuit 20. Specifically, in decision block 915, the memory may store instructions to detect whether the optical element 14 is intact or damaged based on voltage detection. For example, as set forth above, the controller 18 may be pre-programmed, i.e., stored as instructions in the memory, with a level of the voltage to be detected from the electrical circuit 20 that results from the voltage supplied at the voltage supply 38 when the electrical circuit 20 is intact. In such an example, the memory may store instructions to wait for voltage at a level that indicates that the electrical circuit 20 is intact. As another example, the memory may store instructions to detect the voltage other than a voltage indicating that the electrical circuit 20 is intact.

In block 920, the memory may store instructions to power the light emitter 16 when the optical element 14 is intact. For example, the memory may store instructions to power the light emitter 16 when voltage detected from the electrical circuit 20 is at a level indicating that the electrical circuit 20 is intact. In other words, when no damage is detected, the memory stores instructions to power the light emitter 16 aimed at the optical element 14 to diffuse the light with the optical element 14. After powering the light emitter 16, the method 900 may be restarted. In other words, the memory may store instructions to power the light emitter 16 only if the voltage received from the electrical circuit 20 indicates that the electrical circuit 20 is intact.

In block 925, the memory may store instructions to disable operation of the light emitter 16 when the optical element 14 is damaged. Specifically, the memory may store instructions to disable operation of the light emitter 16 in response to detection of voltage from the electrical circuit 20 indicating that at least part of the electrical circuit 20 is broken. For example, the memory may store instructions to disable the light emitter 16 in the absence of voltage at a level indicating that the electrical circuit 20 is intact, e.g., resulting from a different voltage across the electrical circuit 20 due to a break in the electrical circuit 20. In such an example, the decision to disable the light emitter 16 may be made when a predetermined time period lapses after the supply of voltage to the electrical circuit 20 in block 905 without detection of voltage indicating the optical element 14 is intact. As another example, the memory may store instructions to disable the light emitter 16 in response to detecting voltage at a level that indicates the optical element 14 is damaged. As set forth above, disabling operation of the light emitter 16 may include not powering the light emitter 16 and/or taking an active step to disable the power emitter and/or prevent emission of light from the exit window 34.

With reference to FIG. 10, the method 1000 may use the example of the optical element 14 shown in FIGS. 6-7C. In block 1005, the memory stores instructions to supply voltage to the electrical circuit 20. As described above, the controller 18 may supply the voltage directly to the electrical circuit 20 or may instruct an intermediate component to supply the voltage to the electrical circuit 20. The level of voltage supplied to the electrical circuit 20 is known, i.e., predetermined.

Specifically, as shown in block 1005, the memory stores instructions to supply voltage to a first terminal 48. In block 1010, the memory stores instructions to detect voltage from the first terminal 48 through at least one of the other terminals 48. In other words, the voltage is conducted through the layer 24 from the first terminal 48 to the other terminals 48. In the examples, shown in FIGS. 7A and 7C, the memory stores instructions to detect voltage with each other terminals 48 (i.e., the terminals 48 other than the first terminal 48). For example, as set forth above, the controller 18 may be pre-programmed, i.e., stored as instructions in the memory, with a level of the voltage to be detected at the other terminals 48 that results from the voltage supplied at the first terminal 48 when the electrical circuit 20 is intact. As another example, the memory may store instructions to detect the voltage other from the terminals 48 other than a voltage indicating that the electrical circuit 20 is intact.

In decision block 1015, the memory includes instructions to detect whether the optical element 14 is intact or damaged based on voltage detection. In the event the electrical circuit 20 is broken, the method 1000 proceeds to blocks 1020 and 1025 to disable operation of the light emitter 16 (as described above with reference to block 925) and potentially notify the vehicle 30 (as described above with reference to block 930).

As shown in FIG. 10, in the event the electrical circuit 20 is intact at block 1015, the memory may include instructions to supply voltage to a second terminal 48 (block 1030), detect voltage at the other terminals 48 (block 1035), and detect whether the optical element 14 is intact or damaged based on voltage detection (block 1040). The memory may store instructions to cycle through a routine of supplying voltage to different ones of the terminals 48 and detecting the voltage across the optical element 14 to determine integrity of the optical element 14. In other words, the routine of supplying voltage to different ones of the terminals 48 results in a grid of current paths (FIG. 7C) to increase the test area of the optical element 14 that is checked for integrity, as described above. It should be appreciated that the method 1000 shown in FIG. 10 cycles through two of the terminals 48 for supply voltage, and these steps may be repeated for any number of terminals 48.

As another example, in the event the electrical circuit 20 is intact at block 1015, the method 1000 may skip to block 1055 and power the light emitter 16, i.e., based only on supplying voltage to the first terminal 48 and detecting voltage at the other terminals 48. In such an example, the method 1000 may be restarted at block 1005 after block 1055. In other words, the first terminal 48 is again supplied with voltage and integrity of the optical element 14 is determined based on voltage detection at the other terminals 48. As another example, another terminal 48 may be supplied with voltage and integrity of the optical element 14 is determined based on voltage detection at the other terminals 48, i.e., the method 1000 may proceed from block 1055 to block 1030 to perform steps 1030, 1035, and 1040 beginning with supplying voltage to a second terminal 48.

In block 1055, the light emitter 16 is powered (as described above with reference to block 920) based on the determination that the optical element 14 is intact.

The powering of the light emitter 16 in blocks 920 and 1055 results in emission of light from the light emitter 16 to the optical element 14, which diffuses the light and directs the light through the exit window 34 to illuminate the scene. The memory stores instructions to detect a range of an object illuminated by the light diffused by the optical element 14. The methods 900, 1000 are repeated before each time the light emitter 16 is powered so that the optical element 14 is tested before each light emission.

Throughout this disclosure, use of “in response to” and “upon determining” indicates a causal relationship, not merely a temporal relationship. The numerical adjectives such as “first,” “second,” etc. are used herein as identifiers and do not indicate order, importance, or relative arrangement. The disclosure has been described in an illustrative manner, and it is to be understood that the terminology which has been used is intended to be in the nature of words of description rather than of limitation. Many modifications and variations of the present disclosure are possible in light of the above teachings, and the disclosure may be practiced otherwise than as specifically described.

What is claimed is:

1. A system comprising:
an optical element;
a light emitter aimed at the optical element;
a controller in communication with the light emitter; and
an electrical circuit across the optical element and in communication with the controller.

2. The system of claim 1, wherein the optical element has a light-shaping region and the electrical circuit is across the light-shaping region.

3. The system of claim 1, further comprising a casing and an exit window through the casing, wherein the optical element directs light from the light emitter toward the exit window.

4. The system of claim 3, wherein the optical element is designed to diffuse the light from the light emitter.

5. The system of claim 1, wherein the controller is programmed to control the light emitter based on voltage received by the controller from the electrical circuit.

6. The system of claim 1, wherein the controller is programmed to power the light emitter based on voltage received by the controller from the electrical circuit indicating that the electrical circuit is intact.

7. The system of claim 6, wherein the controller is programmed to disable operation of the light emitter based on voltage received by the controller from the electrical circuit indicating that at least a portion of the electrical circuit is broken.

8. The system of claim 1, wherein the electrical circuit includes a wire extending across the optical element.

9. The system of claim 1, wherein the optical element includes a layer of electrically-conductive material that forms a portion of the electrical circuit.

10. The system of claim 9, wherein the electrical circuit includes terminals spaced from each other on the electrically-conductive material and in communication with the controller.

11. The system of claim 10, wherein the terminals are disposed on a peripheral edge of the optical element.

12. A controller having a processor and memory storing instructions executable by the processor to:
detect voltage from an electrical circuit across an optical element; and
control operation of a light emitter aimed at the optical element based on the level of voltage detected from the electrical circuit.

13. The controller as set forth in claim 12, wherein the instructions include instructions to power the light emitter only if the voltage detected from the electrical circuit indicates that the electrical circuit is intact.

14. The controller as set forth in claim 12, wherein the instructions include instructions to power the light emitter in response to detection of voltage from the electrical circuit indicating that the electrical circuit is intact.

15. The controller as set forth in claim 14, wherein the instructions include instructions to disable operation of the light emitter in response to detection of voltage from the electrical circuit indicating that at least part of the electrical circuit is broken.

16. The controller as set forth in claim 12, wherein the instructions include instructions to disable operation of the light emitter in response to detection of voltage from the electrical circuit indicating that at least part of the electrical circuit is broken.

17. The controller as set forth in claim 16, wherein the instructions include instructions to supply voltage to a first terminal of a plurality of terminals on the optical element and to detect voltage from the first terminal through at least one other of the terminals.

18. The controller as set forth in claim 17, wherein the instructions include instructions to supply voltage to a second terminal of the plurality of terminals and to detect voltage from the second terminal through at least one other of the terminals.

19. A method comprising:
supplying voltage to an electrical circuit across an optical element;
detecting voltage from the electrical circuit;
controlling operation of a light emitter aimed at the optical element based on the level of voltage detected from the electrical circuit.

20. The method as set forth in claim 19, wherein controlling operation of the light emitter includes powering the light emitter in response to detection of voltage from the electrical circuit indicating that the electrical circuit is intact.

21. The method as set forth in claim 20, wherein controlling the operation of the light emitter includes, after powering the light emitter, disabling operation of the light emitter in response to detection of voltage from the electrical circuit indicating that at least part of the electrical circuit is broken.

22. The method as set forth in claim 19, wherein controlling the operation of the light emitter includes disabling operation of the light emitter in response to detection of voltage from the electrical circuit indicating that at least part of the electrical circuit is broken.

23. The method as set forth in claim 19, wherein supplying voltage includes supplying voltage to a first terminal of a plurality of terminals on the optical element and detecting voltage from the first terminal with at least one other of the terminals.

24. The method as set forth in claim 19, wherein supplying voltage includes supplying voltage to a second terminal of the plurality of terminals and detecting voltage from the second terminal with at least one other of the terminals.

25. The method as set forth in claim 24, further comprising powering the light emitter after detecting voltage from the first terminal and before supplying voltage to the second terminal.

26. The method as set forth in claim 19, further comprising powering the light emitter and detecting a range of an object illuminated by the light emitted from the light emitter.
